(19) United States
(12) Patent Application Publication
(10) Pub. No.: US 2026/0223346 A1
(43) Pub. Date: Jul. 30, 2026

(54) SYSTEM WITH AT LEAST ONE PRODUCT CARRIER AND AT LEAST ONE DATA MEDIUM, METHOD FOR PROVIDING A SYSTEM, AND METHOD FOR DETERMINING A CHARACTERISTIC DATA RECORD STORED ON A DATA MEDIUM OF A SYSTEM

(71) Applicant: TDK Electronics AG, Muenchen (DE)

(72) Inventors: Peter Krcho, Deutschlandsberg (AT); Thomas Stendel, Rangsdorf (DE); Martin Zennig, Potsdam (DE); Holger Hegner, Stahnsdorf (DE); Sujan Chandra Das, Deutschlandsberg (AT); Volkmar Schmidt, Bad Brambach (DE)

(21) Appl. No.: 19/157,904

(22) PCT Filed: Feb. 23, 2024
(86) PCT No.: PCT/EP2024/054630

§ 371 Date: Aug. 19, 2025

(30) Foreign Application Priority Data
Mar. 1, 2023 (DE) 10 2023 105 047.8

(51) Int. Cl. H05K 13/08; H05K 13/00

(52) U.S. Cl. CPC H05K 13/084; H05K 13/0015

(57) ABSTRACT

In an embodiment a system includes at least one product carrier and at least one data medium, wherein a plurality of electronic components are arranged on the product carrier, wherein each of the electronic components has a unique position on the product carrier, wherein each of the electronic components is removable from the product carrier by a user manually or by a machine, wherein the product carrier has a unique identifier, wherein an individually assigned characteristic data record is stored on the data medium for each of the electronic components, and wherein the individually assigned characteristic data record stored on the data medium is obtainable for each of the electronic components with the unique identifier of the product carrier and the unique position on the product carrier.

### CROSS-REFERENCE TO RELATED APPLICATIONS

This patent application is a national phase filing under section 371 of PCT/EP 2024/054630, filed Feb. 23, 2024, which claims the priority of German patent application no. 102023105047.8, filed Mar. 1, 2023, each of which is incorporated herein by reference in its entirety.

### TECHNICAL FIELD

A system with at least one product carrier and at least one data medium, a method for providing a system, and a method for determining a characteristic data record stored on a data medium of a system are provided.

### BACKGROUND

Manufacturers usually provide data sheets for electronic components, such as passive electronic components, from which users, i.e., customers who purchase and use such components, can obtain the specifications, i.e., the characteristic data and associated tolerances. Since a data sheet is usually provided for a specific component, the characteristic data and tolerances result from the variation in manufacturing and measurements that apply to the entire component series. When using the specifications with the tolerances specified for the entirety of the components according to the data sheet, limited product performance, i.e., in particular limited accuracy, may therefore result for the individual component. It follows that, for example, in the case of NTC thermistors (NTC: “negative temperature coefficient”), the temperature accuracy in measurement applications depends on the tolerances specified in the data sheet and that, therefore, there may be a difference in the temperature determined by measurement from component to component.

In principle, it is possible to reduce the wide variation in product characteristics obtained during manufacture, for example R and/or B values for NTC components, and thus the tolerances, by means of targeted sorting. In applications such as temperature measurement with high requirements for measurement accuracy, the NTC components must therefore be pre-sorted in order to achieve a narrow resistance tolerance and/or B value tolerance. This means that not all components from a production batch can be used, which results in high scrap rates and thus higher costs. For example, if the desired tolerance of the nominal resistance RR of NTC components is reduced from ±5% to ±1%, the scrap rate increases significantly. A further reduction in the resistance tolerance from ±1% to, for example, ±0.5% or ±0.1% would lead to a disproportionate increase in scrap, as ultimately only a small proportion of the parts produced would meet the specification.

Alternatively, attempts can be made to reduce the variation in the manufacturing method in order to reduce tolerances on the one hand and prevent excessive scrap on the other. However, this is not always feasible, or at least only possible at significantly higher cost.

The achievable accuracy in the performance of an electronic component is therefore limited by the tolerances relating to the production series, whereby a further, particularly significant, improvement in performance through a further reduction in tolerances is not economically feasible. Thus, when high performance is required, it is often unavoidable that a component must be calibrated by the customer. In the example of the manufacture of devices for temperature measurement with NTC thermistors, this means that each thermistor must be individually calibrated by measuring each of the NTC thermistors, which leads to high costs for the customer.

### SUMMARY

Embodiments provide a system with at least one product carrier and at least one data medium. Further embodiments provide a method for providing a system. Yet other embodiments provide a method for determining a characteristic data record stored on a data medium of a system.

According to at least one embodiment, a system has at least one product carrier. A plurality of like electronic components are arranged on the at least one product carrier. The product carrier with the electronic components can represent a sales unit in the form of which electronic components are delivered. In other words, a product carrier with electronic components arranged thereon can be the smallest delivery quantity if a user wishes to purchase electronic components. The product carrier has a certain number of positions, wherein at each of which, at least in a delivery state of the product carrier, one electronic component is arranged.

In particular, the electronic components, which may also be referred to as components for short in the following, may be passive electronic components, for example selected from thermistors such as PTC thermistors (PTC: “positive temperature coefficient”) and NTC thermistors, varistors, resistors, capacitors, inductors. Even though the description here and in the following refers mainly to electronic components, other components are also possible, which are delivered in pluralities on product carriers. Furthermore, the term “component” can also include devices consisting of several components, i.e., multi-component systems and assemblies that are delivered on product carriers.

Each of the electronic components can be detached by a user from at least one product carrier, so that the components are detachably fastened to the at least one product carrier. A “user” can be a human user or a directly or indirectly controlled machine or a programmed machine. Thus, components can be detached manually or by machine. An advantage of the system described here can accordingly result in purely mechanical processing of product carriers and the resulting avoidance of human-caused errors, such as, above all, the mixing up of components during assembly. “Detachably fastened” can mean, in particular, that the electronic components remain on the product carrier during normal use until they are detached from the product carrier by a user for further use, wherein each of the electronic components can be separated from the product carrier individually and without damage to the component. The product carrier may, for example, comprise a plastic carrier or be a plastic carrier on which the plurality of components are detachably fastened for a user. For example, the electronic components may be detachably fastened to the product carrier in slots into which, for example, contact wires of the components are inserted, and/or by adhesive connections and/or by clamping connections. Furthermore, the product carrier may, for example, comprise or be a package, in particular a plastic package or a composite package such as a blister package or a so-called “tape and reel” package, which comprises a chamber sealed with a film for each component, from which the respective component can be pressed out.

According to a further embodiment, the at least one product carrier has a unique identifier. The unique identifier makes the at least one product carrier clearly identifiable and distinguishable from other product carriers. For example, the system may comprise a plurality of product carriers, each with a plurality of similar electronic components, wherein each product carrier has a unique identifier that differs from all other product carriers in the plurality of product carriers, so that each of the product carriers in the system can be uniquely identified by a user and distinguished from all other product carriers in the system. For example, the system may comprise a series, also referred to as a batch or lot, of electronic components divided into groups, each comprising a plurality of components, each group being arranged on a product carrier of a plurality of product carriers. Although the following description refers primarily to one product carrier, the features and embodiments described apply equally to all product carriers in the system.

According to a further embodiment, the electronic components are free of any individual identifier. This may mean, in particular, that the components themselves do not have any identifier at all or that all components have the same identifier, which may be, for example, a product identifier such as a product number that is the same for all components. The electronic components can thus preferably be essentially indistinguishable by a user once they have been removed from the product carrier.

According to a further embodiment, each of the electronic components has a unique position on the at least one product carrier. The electronic components can, for example, be arranged linearly, i.e., lined up next to each other in a row, or in a matrix, i.e., orthogonally in rows and columns, or even hexagonally, on the at least one product carrier. As long as an electronic component is arranged on the at least one product carrier, said electronic component can be distinguished from all other components on the product carrier by means of its unique position in that said other components have other unique positions on the product carrier.

For example, the unique positions of the electronic components on the product carrier can be defined by a numbering. In other words, each position on the at least one product carrier at which an electronic component is arranged in the delivery state of the product carrier can be marked with a number. The numbering can preferably begin with “1” at a specified first position and designate the other positions with ascending numbers. Instead of numbering, other position identifiers such as letters, other characters, color coding, or combinations of the aforementioned position identifiers may also be provided. It may also be the case that only a first position is marked, for example with a “1” or another of the aforementioned position identifiers, and the other positions result from the geometric arrangement in relation to the first position.

Furthermore, it may also be possible for the unique positions to be defined by the geometric arrangement in relation to the unique identifier and/or to a structural marking. For example, the unique identifier may be arranged on the front of the product carrier and the positions of the electronic components may be clearly identifiable, when looking onto the front, in their geometric relationship to the unique identifier, for example if the electronic components are arranged linearly or in a matrix, i.e., in rows and columns, on the product carrier in such a way that, with respect to the position of the unique identifier, a unique position of a first electronic component is defined, from which the unique positions of the other electronic components can be determined. Furthermore, structural marking may also be provided, for example, by identifying the unique position of a first electronic component from which the unique positions of all other electronic components are determined. A structural marking may be provided, for example, in the form of a geometric shape on the product carrier, such as a bevel, a bulge such as a raised area or a nose, or an indentation such as a recess or groove.

Furthermore, a color marking, such as a colored dot, may also be provided as a structural marking.

According to a further embodiment, the unique identifier of the at least one product carrier is a uniquely assigned combination of numbers and/or letters which is arranged on the at least one product carrier in unencoded or preferably encoded form. For example, the unique marking may comprise a one-dimensional or two-dimensional barcode. A one-dimensional barcode can, for example, be a striped barcode or comprise a striped barcode. A two-dimensional barcode can, for example, be a data matrix code or a QR code (QR: “quick response”) or comprise such code. The unique identifier can also comprise or be formed of several character combinations and/or barcodes.

According to a further embodiment, the system has at least one data medium on which an individually assigned characteristic data record is stored for each of the electronic components. Each of the characteristic data records may contain one or more characteristic data parameters, which are selected, for example, from one or more individual measurement data, production batch characteristic data, correction factors, and tolerances. The characteristic data parameters may relate, for example, to electrical quantities or dependency factors that are typical for the electronic components. For example, in the case of NTC thermistors as electronic components, an individually measured nominal resistance and/or a B value and/or a correction factor with regard to a parameter from an assigned data sheet and/or one or more tolerance values for one or more parameters may be stored for each component. With the help of the individually assigned characteristic data record, which contains, for example, an individually measured nominal resistance, a user may be able to perform more accurate temperature measurements than if these were performed using a general average nominal resistance with a large tolerance specified in a data sheet for the entire series.

According to a further embodiment, the individually assigned characteristic data record stored on the data medium can be obtained for each of the electronic components on the at least one product carrier using the unique identifier of the product carrier and the unique position on the product carrier. The unique identifier of the product carrier and the unique position on the product carrier makes it possible to identify and retrieve the corresponding individually assigned characteristic data record for each electronic component.

For example, the data medium may be a data storage device that is accessible to a user locally or via a network connection. For example, the data medium may be accessible to the user via a local or global network connection. In this case, there is a central data carrier on which the individually assigned identification data records for the electronic components are stored. For example, it may be a data carrier from the manufacturer of the electronic components, which is accessible, for example, via the internet and, in particular, a suitable website or a suitable computer program or a script provided for integration into a computer program, and from which the individually assigned characteristic data record can be obtained for each electrical component by using at least the unique identifier of the product carrier or the unique identifier of the product carrier and the unique position on the product carrier.

Furthermore, it may also be possible for the data medium to be a data carrier that can be used locally by the user. The locally usable data carrier can, for example, be provided by the manufacturer of the electronic components. The locally usable data carrier may be, for example, a CD-ROM or a memory stick. Using a standardized local or web-based computer program, the individually assigned characteristic data record can be retrieved from the local data carrier for each electrical component by entering the unique identifier of the product carrier and the unique position on the product carrier.

Furthermore, the data medium can also be arranged on the product carrier, for example. In this case, the data medium can be permanently connected to the product carrier under normal conditions. For example, the data medium can comprise or be an NFC chip or a two-dimensional barcode. Such a data medium can in particular contain the identification data records for all components arranged on the product carrier.

According to a further embodiment, in a method for providing a system as described herein, a plurality of like electronic components are manufactured. A characteristic data record can be determined for each of the electronic components. Furthermore, each of the electronic components can be arranged at a unique position on a product carrier having a unique identifier. Furthermore, the characteristic data record, the associated unique identifier and the unique position can be stored in a data medium for each of the electronic components. The characteristic data record for a component can be determined before or after the component is attached to the product carrier.

According to a further embodiment, in a method for determining a characteristic data record stored on a data medium, which is assigned to an electronic component on a product carrier of a predefined system, the unique identifier of the product carrier is determined. Furthermore, the unique position of the electronic component on the product carrier is determined. Furthermore, the characteristic data record can be obtained from the data medium using the determined unique identifier and the determined unique position. This can mean that the individually assigned characteristic data record can be retrieved for each component individually. Furthermore, it may also be possible, for example, to use the unique identifier to retrieve the characteristic data records of all components on the product carrier from the data medium in the form of a characteristic data record collection and to obtain the individually assigned characteristic data record for a specific component from the characteristic data record collection using the unique position. The characteristic data record collection can, for example, be a suitable file in which the characteristic data records are contained at least with the assigned unique position and the assigned unique identifier of the associated product carrier.

The features and embodiments described in connection with the system also apply to the method for providing the system and to the method for determining a characteristic data record. Furthermore, the features and embodiments described in connection with the method for providing the system and the features and embodiments described in connection with the method for determining a characteristic data record also apply to the system.

In the system and methods described here, an assignment can be made in the manner described above between individual, specific characteristic data records determined for each electronic component, such as measurement data, and the physically existing electronic components on the at least one product carrier. By retrieving and using the characteristic data, a user can thus utilize the individual characteristics of each component in an electronic device, thereby improving the performance of the overall system.

Characteristic data records, at least for the purchased electronic components, such as individual measurement data from the manufacturing method, can be made available to a user, i.e., a customer of the manufacturer of the electronic components, in a data file on the data medium. Such a data file can be made available, for example, by means of a global network connection, i.e., an internet connection and thus preferably via an online platform, in addition to at least one product carrier with the electronic components. The characteristic data records, i.e., individual parameters with the part number, can be stored in the data file. In addition, an assignment to the product carrier, i.e., for unique identifier of the product carrier, is included, which may contain information about the product carrier and the production batch, for example. The product carrier has this unique identifier as an identifier, i.e., a code, which can be used to retrieve the data. This ensures that each electronic component is uniquely assigned to a characteristic data record. The components themselves are not identifiable, i.e., they cannot be distinguished from one another by individual identifiers. For this reason, the characteristic data record is assigned to the component via an identifiable product carrier and a defined arrangement, e.g., a defined sequence of the components on the product carrier.

The use of individual characteristic data for the components and the resulting significantly narrower tolerances enables improved accuracy in applications involving the components, for example in electronic devices in which one or more of the components are used. For example, temperature sensors may exhibit lower variation and lower errors in temperature measurement from component to component, which can lead to higher measurement precision without additional temperature calibration in the application. This means that temperature calibration is no longer necessary, especially on the customer side, when high measurement precision is required. The use of characteristic data may also make it possible to supply all or at least almost all of the components produced. This can significantly reduce the scrap rate. Increased variation in the manufacturing method does not therefore lead to a deterioration in performance in a device containing one or more of the electronic components when the individual characteristic data record is used.

Instead of single characteristic data records, i.e., individual measured values, production batch characteristic data records can also be used as characteristic data parameters in the characteristic data records, which can be determined by random sampling. In the case of NTC thermistors, for example, this can be applied to the nominal resistance and the B value. To determine the B value, the resistances of the components must be measured at at least two temperatures. The B value is then calculated from these values. This means that the use of production batch data can be a cost-effective compromise between providing and measuring individual component values and using the tolerances specified in the general data sheet, since a data sheet must be valid for all production batches and therefore takes into account the total variation range in a single data sheet.

### BRIEF DESCRIPTION OF THE DRAWINGS

Further advantages, advantageous embodiments, and further developments become apparent from the embodiments described below in the following with the figures.

FIGS. 1A and 1B show schematic illustrations of a system according to an embodiment;

FIGS. 2A and 2B show schematic illustrations of a method for providing a system according to further embodiments;

FIG. 3 shows a schematic illustration of a method for determining a characteristic data record stored on a data medium of a system according to a further embodiment;

FIGS. 4A to 4G show schematic illustrations of a product carrier according to further embodiments;

FIGS. 5A and 5B show schematic illustrations of a system according to a further embodiment; and FIG. 6 shows a schematic illustration of a product carrier according to a further embodiment.

In the embodiments and figures, identical, similar, or functionally equivalent elements may be designated by the same reference signs. The elements shown and their relative sizes in regard to each other are not to be regarded as to scale; rather, individual elements, such as layers, components, structural elements, and areas, may be shown enlarged for clarity and/or better understanding.

### Detailed Description of Illustrative Embodiments

In connection with the figures described below, several examples of implementation are explained for the purpose of better understanding. Purely by way of example and without limitation, the electronic components in the embodiments are embodied as NTC thermistors, which have an NTC element soldered to supply lines and molded with a plastic such as epoxy.

Alternatively, the electronic components may also be embodied differently, as described above in the general part.

NTC thermistors are ideal for use in the automotive industry, medical technology, factory automation, and field instruments because they are very small, respond quickly, and are available in a wide variety of sensor housings and application-specific designs. While it is possible to manufacture NTC thermistors with an individual resistance tolerance of, for example, ±0.3%, manufacturing variations mean that the manufacturing tolerances typically specified in data sheets, which refer to the entire production series, are many times higher, for example ten times higher. Circuit designers have had to cope with this manufacturing tolerance in the past, as individual calibration requires expert knowledge and is time-consuming and not always possible in production.

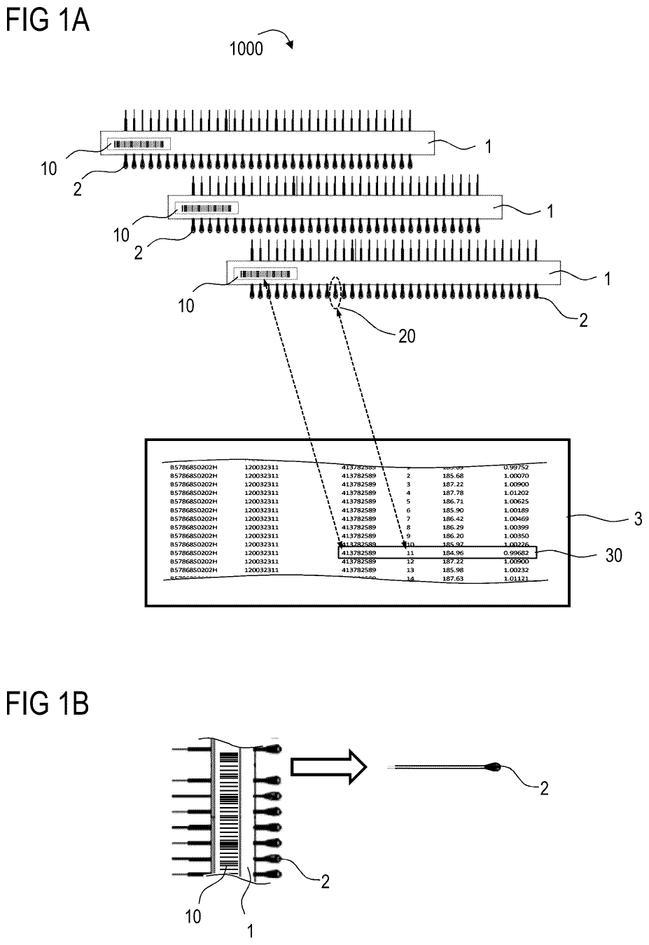

In connection with FIGS. 1A and 1B, an embodiment of a system 1000 is shown in which the disadvantage of manufacturing tolerance can be avoided, without the user having to perform individual calibration for each electronic component.

The system 1000 comprises at least one product carrier 1. In particular, the system 1000 can also comprise several product carriers 1. Three product carriers 1 are shown in FIG. 1 as examples, but this should not be understood as a limitation. A plurality of like electronic components 2 are arranged on each of the product carriers 1. All components 2 of the system 1000 are therefore identical in construction and are manufactured in series production. Each product carrier 1 with electronic components 2 represents a unit. In particular, each product carrier 1 with the electronic components 2 arranged thereon represents a sales unit in the form in which the electronic components 2 are delivered and can be purchased. Thus, a product carrier 1 with the electronic components 2 arranged thereon forms the smallest delivery quantity if a user wishes to purchase electronic components 2. The product carrier 1 has a certain number of positions at which at least one electronic component 2 is arranged in the delivery state of the product carrier 1. For example, the system 1000 can have at least one series of electronic components 2, which are divided into groups of a plurality of components 2, each group being arranged on a product carrier 1 of a plurality of product carriers 1. The following description applies to a system 1000 with any number of product carriers 1. The term “at least one product carrier” can therefore represent any product carrier 1 and, in particular, all of the product carriers 1 of the system 1000. Furthermore, each product carrier 1 has 35 electronic components 2, purely by way of example. However, any number of electronic components 2 greater than or equal to 2 is possible on a product carrier 1.

Each of the electronic components 2 is detachably fastened to the at least one product carrier 1. Each of the electronic components 2 can thus be separated from the product carrier 1 individually and without damage to the component 2 by a user, i.e. manually or by machine, as indicated in FIG. 1B in a section of a product carrier 1 from FIG. 1A. The at least one product carrier may, as shown in FIG. 1A, comprise a rod-shaped carrier body on which the electronic components 2 are arranged linearly, i.e., along a row, next to one another. In particular, the carrier body in the embodiment shown may have insertion slots in the form of openings into which the electronic components 2 are inserted and in which the electronic components 2 are held. For example, the product carrier 1 may comprise a plastic carrier or be a plastic carrier on which the plurality of electronic components 2 are detachably fastened for a user. For example, the electronic components 2 can be detachably fastened to the product carrier 1 at the insertion locations of the product carrier 1, into which the contact wires of the components 2 are inserted, by means of an adhesive connection or a clamping connection.

The shown embodiment of the product carrier 1 is purely exemplary and is not to be understood as limiting. For example, the product carrier 1 may also have a different shape and/or a different fastening option for the electronic components 2. Furthermore, the product carrier 1 may also have or be a packaging, in particular a plastic packaging or composite packaging such as blister packaging or tape-and-reel packaging.

The at least one product carrier 1 has a unique identifier 10. In the case of the plurality of product carriers 1 shown, this means in particular that each product carrier 1 has a unique identifier 10 that is different from all other product carriers 1 of the system 1000. The unique identifier 10 makes each of the product carriers 1 clearly identifiable and distinguishable from all other product carriers 1 of the system 1000. The features and characteristics of the unique identifier 10 are explained in more detail in connection with the figures described in the following.

The electronic components 2 are free of any individual identifier. This can mean, in particular, that the components 2 themselves do not bear any identifier at all, as indicated in FIGS. 1A and 1B. Furthermore, all components may have the same marking, which may be, for example, a general product identifier such as a product or type number, but which is the same for all components 2. The electronic components 2 are therefore essentially indistinguishable to a user once they have been detached from the product carrier 1.

Each of the electronic components 2 has a unique position 20 on the at least one product carrier 1, wherein, purely by way of example, a position 20 is highlighted in FIG. 1 by the dashed border. As long as an electronic component 2 is arranged on the at least one product carrier 1, the said electronic component 2 can be distinguished from all other components 2 on the product carrier by means of its unique position 20, in that the said other components 2 have other unique positions 20 on the product carrier 1. Features and characteristics of the unique positions and their determination are further explained in connection with the figures described in the following.

Furthermore, the system 1000 has at least one data medium 3 on which an individually assigned characteristic data record 30 is stored for each of the electronic components 2 of the at least one product carrier 1. For example, the characteristic data records 30 can be stored in one or more tables or database entries, as indicated in FIG. 1A. Each of the characteristic data records 30, one of which is highlighted in FIG. 1A as an example, may contain one or more characteristic data parameters which are chosen, for example, from one or more individual measurement data, production batch characteristic data, correction factors, and tolerances. For example, in the case of NTC thermistors as electronic components 2, the individually measured nominal resistance and a correction factor can be stored for each component 2. With the help of the individually assigned characteristic data record 30, a user can perform more accurate temperature measurements than if these were performed using a general average nominal resistance with a large tolerance specified in a data sheet for the entire series. For the unique assignment of a characteristic data record 30 to an electronic component 2, the unique identifier 10 of the product carrier 1 on which the relevant electronic component 2 is arranged and the position 20 of the relevant electronic component 2 on this product carrier 1 are provided, as indicated by the dashed arrows in FIG. 1. Thus, for each of the electronic components, the individually assigned characteristic data record 30 stored on the data medium 3 can be obtained using the unique identifier 10 of the product carrier 1 and the unique position 20 on the product carrier 1. The unique identifier 10 of the product carrier 1 and the unique position 20 on the product carrier 1 thus enable a user to identify and obtain the corresponding individually assigned characteristic data record 30 for each electronic component 2.

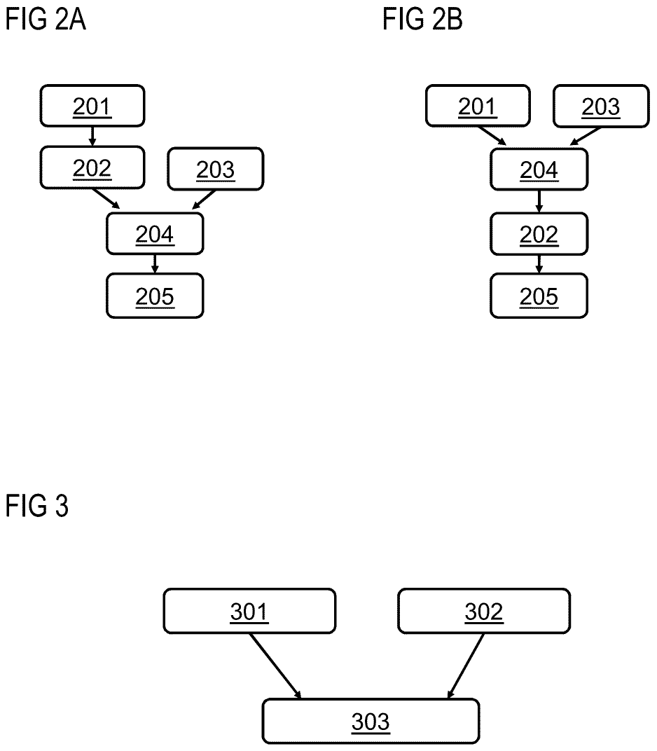

FIGS. 2A and 2B show two embodiments of a method for providing the system 1000. For this, a plurality of like electronic components are manufactured, as indicated by step 201. A characteristic data record is determined for each of the electronic components, which has one or more characteristic data parameters, as indicated by step 202. Furthermore, as indicated by step 203, at least one product carrier with a unique identifier is provided, which may also mean, in particular, that a plurality of product carriers are provided, each of which has a unique identifier that distinguishes it from all other product carriers in the system. In a further step 204, each of the electronic components is arranged on a product carrier at a unique position. In a further step 205, the characteristic data record, the associated unique identifier of the product carrier on which the respective component is arranged, and the unique position are stored in a data medium for each of the electronic components. The characteristic data records for the electronic components in step 202 can be determined before the electronic components are arranged on the product carriers in step 204, as indicated in FIG. 2A. Alternatively, the characteristic data records for the electronic components can be determined in step 202 after the electronic components have been arranged on the product carriers in step 204, as indicated in FIG. 2B.

FIG. 3 schematically illustrates the method described in connection with FIGS. 1A and 1B for determining a characteristic data record stored on a data medium that is assigned to an electronic component on a product carrier of the system 1000. For this purpose, the unique identifier of the product carrier is determined in a first step 301. Furthermore, in a step 302, the unique position of the electronic component on the product carrier is determined. In a step 303, the characteristic data record is obtained from the data medium using the determined unique identifier and the determined unique position.

Further features and characteristics of the system and the methods are described in connection with the following figures.

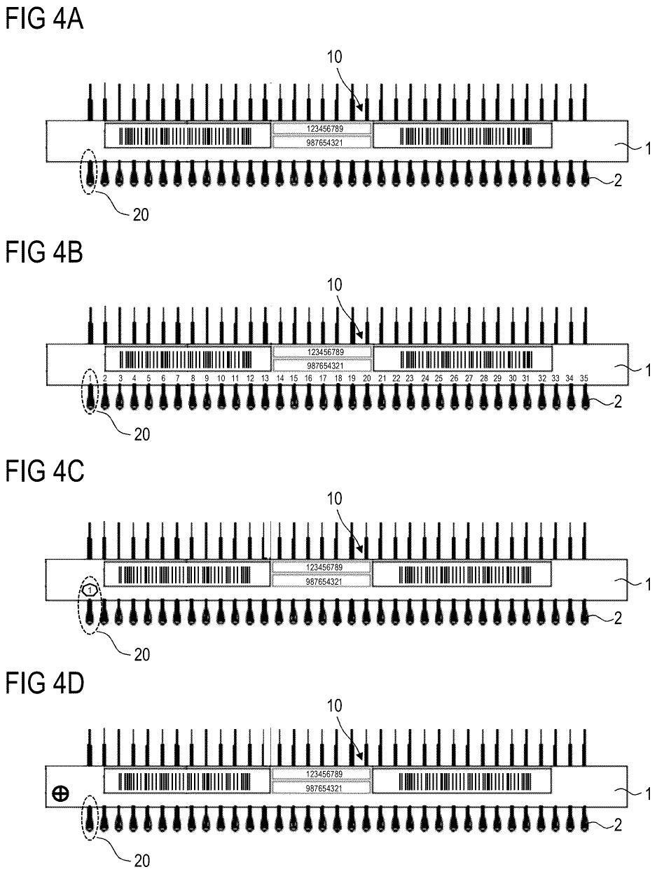

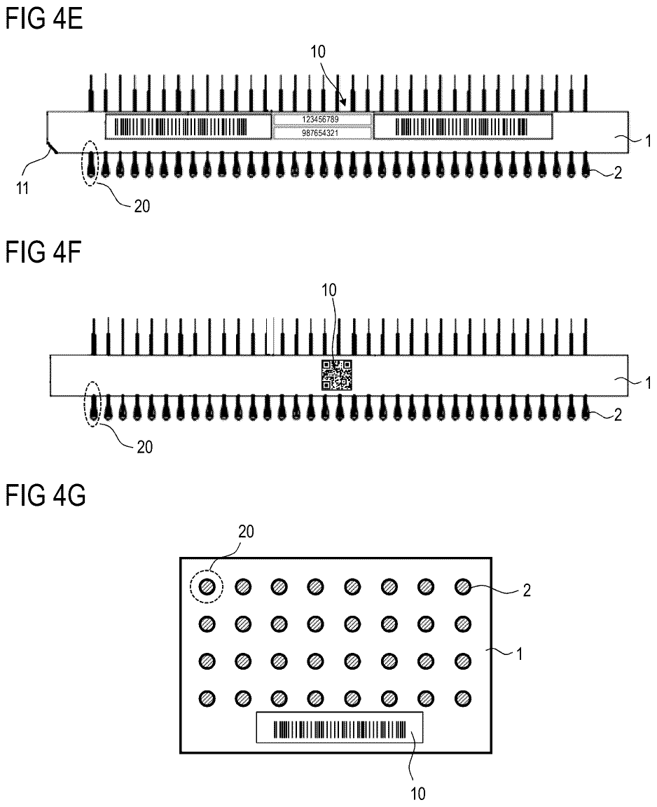

FIGS. 4A to 4G show various embodiments of a product carrier 1 of the system 1000 with electronic components 2 arranged thereon.

As indicated in FIG. 4A, the unique identifier 10 of the product carrier 1 can be a uniquely assigned combination of characters consisting of numbers and/or letters, which is unencoded and/or encoded, in particular encoded, for example, in the form of a barcode, on at least one product carrier 1. In the embodiment shown in FIG. 4A, the unique identifier 10 has, purely by way of example, two-character combinations readable by a user and two one-dimensional barcodes in the form of striped barcodes. Each of the barcodes can, for example, be an encoded form of one of the two user-readable character combinations, so that the unique identifier 10 is easily readable by a user and can also be read into a data processing device such as a computer using a barcode scanner. For example, in the view shown in FIG. 4A, the left barcode and the upper character combination can be a unique product carrier number and the right barcode and the lower character combination can be a production order number, which together can form the unique identifier 10.

The unique positions 20 of the electronic components 2 are defined by their geometric arrangement in relation to the unique identifier. In particular, in the view shown in FIG. 4A, the highlighted unique position 20 of the electronic component 2 located on the left edge can be position “1” on the front side of the product carrier 1 visible in the illustration, which has the unique identifier 10. Starting from this position, it is then possible to count from left to right to determine the unique positions 20 of the other components 2. In the following FIGS. 4B to 4F, the unique position 20 of the electronic component 2 arranged on the left edge, which can be position “1”, is also highlighted.

In the product carrier 1 shown in FIG. 4B, the unique positions 20 of the electronic components on the product carrier 1 are defined by numbering, wherein, as shown, each position 20 can be identified by its own number. Furthermore, only some of the unique positions 20 may be identified by numbers, for example positions “1”, “10”, “20”, and “30”.

In the product carrier 1 shown in FIG. 4C, only the unique position 20 of the electronic component 2 located at the far left in the view shown is marked with the number “1” and further with a symbol, whereas in the product carrier 1 in FIG. 4D, only one symbol is provided on the side of the product carrier 1 from which the unique positions are to be counted. Instead of numbering and/or a symbol, other position identifiers such as letters, other symbols, color coding, or combinations of the aforementioned position identifiers may also be used.

In the product carrier 1 shown in FIG. 4E, a structural marking 11 in the form of a geometric shape is provided on the product carrier to identify the side of the product carrier from which the unique positions 20 are to be counted. The structural marking 11 can be designed as a bevel on the carrier body of the product carrier 1, as shown. Alternatively or additionally, a bulge such as a raised section or a nose, or an indentation such as a recess or groove may also be provided. Furthermore, a colored marking, such as a colored dot, may also be provided as a structural marking 11 for identification purposes.

Alternatively or in addition to the unique identifiers 10 shown in FIGS. 4A to 4E in the form of barcodes and user-readable character combinations, the unique identifier 10 may also comprise a two-dimensional barcode or be formed by a two-dimensional barcode. A two-dimensional barcode may, for example, be a data matrix code or a QR code as shown in FIG. 4F or may comprise such a code.

The electronic components 2 can be arranged on the at least one product carrier 1 in a matrix-like pattern, i.e., in rows and columns, instead of the linear arrangement shown previously, i.e., arranged side by side in a row, as indicated in FIG. 4G. For this purpose, the product carrier 1 can, for example, be designed in the form of a plate or as packaging such as blister packaging. The unique positions 20 of the electronic components 2 can be defined by their geometric relationship to the unique identifier 10. For example, in the view shown in FIG. 4G, the electronic component 2 arranged at the top left on the front side with the unique identifier 10 of the product carrier 1 can have a unique position 20, which is position “1”.

Starting from this, it is then possible, for example, to count row by row from left to right and from top to bottom, so that the column on the left-hand edge can contain the components 2 at positions “1”, “9”, “17”, and “25” one below the other. Furthermore, one or more of the position identifiers described above may also be provided.

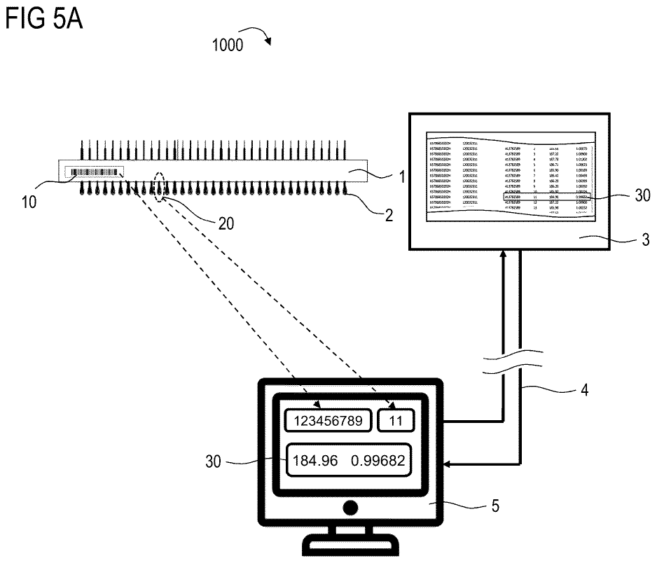

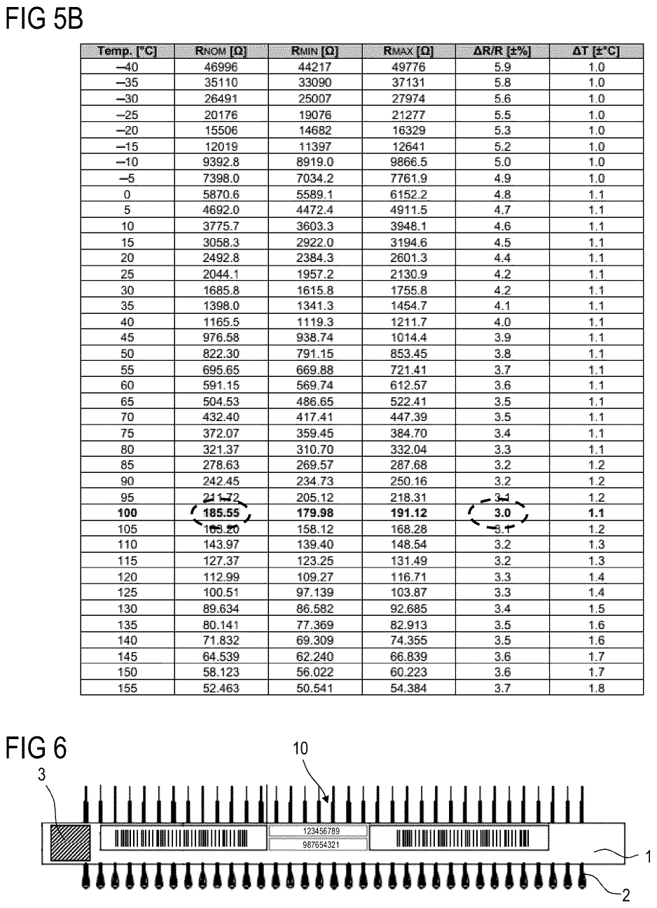

For example, as indicated in the system 1000 shown in FIG. 5A, the data medium 3 described above may be a data storage device that is accessible locally or globally via a network connection 4. In particular, the data medium 3 may be accessible to the user via a local or global network connection 4. In this case, for example, there is thus a central data carrier as data medium 3 on which the individually assigned characteristic data records 30 for the electronic components 2 are stored. This may be a data carrier provided by the manufacturer of the electronic components and accessible, for example, via the internet using a suitable data processing device 4 such as a computer. For this purpose, a suitable website or other suitable computer program may be provided, via which the desired characteristic data records 30 can be retrieved from the data medium 3, as indicated in FIG. 5A.

If the characteristic data record 30 is required for a specific electronic component 2 at a specific unique position 20 of a specific product carrier 1, it can be retrieved by a user entering and/or scanning the unique identifier 10 and the unique position 20 of the electronic component 2 in question on the website or in the computer program. The electronic component 2 in question can then be removed from the product carrier 1 and further processed by a user, for example as part of the manufacture of a device. The associated characteristic data record 30 can be loaded into a memory of the device in a suitable form, for example as part of an application program or firmware, and thus be available for use with the device.

It may also be possible, for example, for the characteristic data records 30 for all electronic components 2 on at least one product carrier 1 to be transmitted by entering or scanning the unique identifier 10, for example in tabular form, in database form, or in the form of another suitable file, so that a user can retrieve the characteristic data record 30 for a specific electronic component 2 from such a file by subsequently entering a unique position 20.

In connection with FIG. 5B, a purely exemplary and non-limiting example of the advantageous use of a characteristic data record 30 obtained in connection with an electronic component 2 embodied as an NTC thermistor element is given. FIG. 5B shows, purely by way of example, a typical data sheet entry for NTC thermistor elements, in which the resistance R_{NOM}, the minimum resistance R_{MIN}, the maximum resistance R_{MAX}, the relative resistance tolerance ΔR/R and the temperature tolerance ΔT are specified as a function of the temperature Temp. As highlighted in FIG. 5B, this indicates a resistance of 185.55Ω with a relative tolerance of 3% for a temperature of 100° C. These values result from the variation described above in the manufacturing method and in the measurement procedure used to determine the values for all components in the entire series. For the embodiment shown, the characteristic data record 30 contains, as indicated in FIG. 5A, a resistance of 184.96Ω at a temperature of 100° C. and a correction factor of 0.99682 in relation to the corresponding data sheet value of 185.55Ω. These characteristic values were measured in a single measurement with the electronic component 2 belonging to this characteristic data record 30, wherein a relative tolerance of 0.3% is given for such a single measurement. This enables a user to use the characteristic data record 30 when using the associated electronic component 2 to adapt the table values from the data sheet to the electronic component 2 in question, so that, thanks to the system 1000 described here, it is possible to take significantly more accurate temperature measurements with the electronic component 2 in question without the user having to perform a temperature calibration themselves.

As an alternative to the data medium 3 accessible via a network connection 4 described above, it may also be possible, for example, for the data medium to be a data carrier that can be used locally by the user. The locally usable data carrier can, for example, be provided by the manufacturer of the electronic components. The locally usable data carrier may, for example, be a CD-ROM or a memory stick. Using a standardized computer program, the individually assigned characteristic data record 30 can then also be retrieved for each electrical component 2 by entering the unique identifier 10 of the at least one product carrier 1 and the unique position 20 on the product carrier 1.

Furthermore, the data medium 3 can also be arranged on the product carrier 1, as indicated in FIG. 6. In this case, the data medium 3 can be permanently connected to the product carrier 1 under normal conditions. For example, the data medium 3 can have or be an NFC chip or a two-dimensional barcode, as indicated in FIG. 6. By reading the chip or the barcode, the characteristic data records of all electronic components 2 on the product carrier 1 can be obtained, for example. In addition, the characteristic data records can preferably be encrypted for data security. The data can then be decrypted using a corresponding code that can be made available to the customer. This ensures that only authorized persons can access the data.

The features and embodiments described in connection with the figures can be combined with each other in accordance with further embodiments, even if not all combinations are explicitly described. Furthermore, the embodiments described in connection with the figures may alternatively or additionally comprise further features in accordance with the description in the general part.

The invention is not limited to the description based on the embodiments. Rather, the invention encompasses every new feature and every combination of features, including in particular every combination of features in the patent claims, even if this feature or combination is not explicitly stated in the patent claims or embodiments.

1-16. (canceled)

17. A system comprising:
at least one product carrier; and
at least one data medium,
wherein a plurality of electronic components are arranged on the product carrier,
wherein each of the electronic components has a unique position on the product carrier,
wherein each of the electronic components is removable from the product carrier by a user manually or by a machine,
wherein the product carrier has a unique identifier,
wherein an individually assigned characteristic data record is stored on the data medium for each of the electronic components, and
wherein the individually assigned characteristic data record stored on the data medium is obtainable for each of the electronic components with the unique identifier of the product carrier and the unique position on the product carrier.

18. The system according to claim 17,
wherein the system comprises a plurality of product carriers, each with the plurality of electronic components, and
wherein each product carrier has a unique identifier different from all other product carriers of the plurality of product carriers.

19. The system according to claim 17, wherein the plurality of electronic components are detachably fastened to the product carrier.

20. The system according to claim 17, wherein the electronic components are free of any individual identifier.

21. The system according to claim 17, wherein each of the characteristic data records contains one or more characteristic data parameters.

22. The system according to claim 21, wherein the one or more characteristic data parameters are selectable from one or more individual measurement data, production batch characteristic data, correction factors, or tolerances.

23. The system according to claim 17, wherein the unique identifier comprises at least one a one-dimensional barcode or a two-dimensional barcode.

24. The system according to claim 17, wherein the electronic components are arranged linearly or in a matrix on the product carrier.

25. The system according to claim 17, wherein the unique positions of the electronic components are defined by numbering.

26. The system according to claim 17, wherein the unique positions of the electronic components are defined by a geometric arrangement in relation to the unique identifier or a structural marking.

27. The system according to claim 17, wherein the data medium is accessible to the user via a network connection.

28. The system according to claim 17, wherein the data medium is a data carrier that is locally usable by the user.

29. The system according to claim 28, wherein the data medium is arranged on the product carrier.

30. The system according to claim 29, wherein the data medium comprises an NFC chip or a two-dimensional barcode.

31. A method for providing the system according to claim 17, the method comprising:
manufacturing the plurality of electronic components;
determining a characteristic data record for each of the electronic components;
providing the product carrier with the unique identifier;
arranging each of the electronic components at the unique position on the product carrier; and
storing the characteristic data record, an associated unique identifier of the product carrier on which a electronic component is arranged, and the unique position of a component on the product carrier in the data medium for each of the electronic components.

32. A method for determining a characteristic data record stored on the data medium, which is assigned to an electronic component on the product carrier of the system according to claim 17, the method comprising:
determining the unique identifier of the product carrier;
determining the unique position of the electronic component on the product carrier; and
obtaining the characteristic data record from the data medium using the determined unique identifier and the determined unique position.
